(19) United States
(12) Patent Application Publication
(10) Pub. No.: US 2014/0110687 A1
(43) Pub. Date: Apr. 24, 2014

(54) NOVEL CONDENSED POLYCYCLIC COMPOUND

(71) Applicant: CANON KABUSHIKI KAISHA, Tokyo (JP)

(72) Inventors: Naoki Yamada, Inagi-shi (JP); Jun Kamatani, Tokyo (JP); Kengo Kishino, Tokyo (JP)

(73) Assignee: CANON KABUSHIKI KAISHA, Tokyo (JP)

(21) Appl. No.: 14/056,283

(22) Filed: Oct. 17, 2013

(30) Foreign Application Priority Data
Oct. 19, 2012 (JP) 2012-232176

(51) Int. Cl. H01L 29/08; C07C 13/465

(52) U.S. Cl. CPC H01L 51/0056; H01L 51/0058; G03G 15/04036
USPC 257/40; 585/27

(57) ABSTRACT

Provided is a novel indenochrysene compound serving as a guest compound suitable for a guest material. In particular, the novel indenochrysene compound is represented by Formula (1), where R₁ to R₁₄ are independently selected from hydrogen atoms and alkyl groups containing one to four carbon atoms, one of X₁ and X₂ is an aryl group, and the other one is a hydrogen atom.

### BACKGROUND OF THE INVENTION

1. Field of the Invention

The present invention relates to a novel condensed polycyclic compound and an organic light-emitting element containing the same.

2. Description of the Related Art

An organic light-emitting element includes two electrodes and an organic compound layer placed therebetween. When electrons and holes are injected into the organic compound layer from the electrodes, excitons of a luminescent organic compound are generated. When the excitons return to the ground state, light is emitted.

United States Patent Application Publication No. 2004-0076853 (hereinafter referred to as Patent Document 1) discloses a compound below. The compound undergoes molecular stacking to have an excimer level. The compound is herein referred to as Compound A.

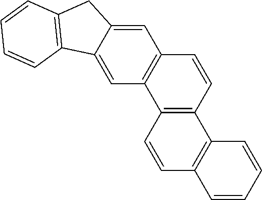 [SMILES: c1ccc2c(c1)Cc1cc3ccc4c5ccccc5ccc4c3cc1-2]

Compound A, which is disclosed in Patent Document 1, is likely to induce intermolecular stacking and is likely to be crystallized. Moreover, Compound A does not have any band gap or T1 energy (lowest excited triplet energy) suitable as a red phosphorescent host material.

### SUMMARY OF THE INVENTION

The present invention provides a novel condensed polycyclic compound represented by the following formula:

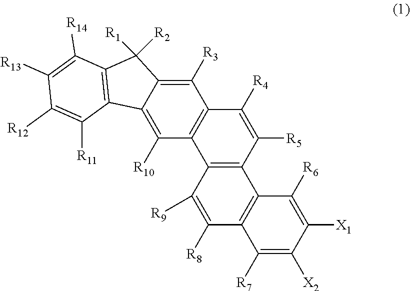

where R₁ to R₁₄ are independently selected from hydrogen atoms and alkyl groups containing one to four carbon atoms, X₁ and X₂ represent a hydrogen atom or an aryl group, one of X₁ and X₂ is the aryl group, and the other one is the hydrogen atom.

The aryl group is at least one selected from the group consisting of a phenyl group, a biphenyl group, a terphenyl group, a fluorenyl group, a naphthyl group, a chrysenyl group, a triphenylenyl group, and a phenanthryl group.

The aryl group may be substituted with an alkyl group containing one to four carbon atoms, a phenyl group, a biphenyl group, a terphenyl group, a fluorenyl group, a naphthyl group, a chrysenyl group, a triphenylenyl group, or a phenanthryl group.

The aryl group may have a substituent substituted with an alkyl group containing one to four carbon atoms.

Further features of the present invention will become apparent from the following description of exemplary embodiments with reference to the attached drawing.

### BRIEF DESCRIPTION OF THE DRAWINGS

The figure is a schematic sectional view of an exemplary display device including an organic light-emitting element according to an embodiment of the present invention and an active element connected to the organic light-emitting element.

### DESCRIPTION OF THE EMBODIMENTS

An embodiment of the present invention provides a novel condensed polycyclic compound having a band gap and T1 energy suitable as a red phosphorescent host.

The condensed polycyclic compound is represented by the following formula:

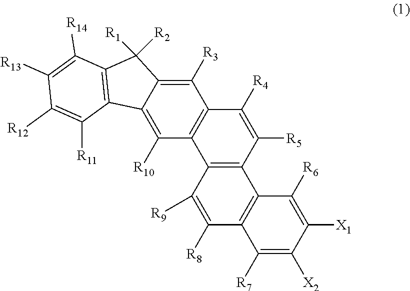

where R₁ to R₁₄ are independently selected from hydrogen atoms and alkyl groups containing one to four carbon atoms, X₁ and X₂ represent a hydrogen atom or an aryl group, one of X₁ and X₂ is the aryl group, and the other one is the hydrogen atom.

The aryl group is at least one selected from the group consisting of a phenyl group, a biphenyl group, a terphenyl group, a fluorenyl group, a naphthyl group, a chrysenyl group, a triphenylenyl group, and a phenanthryl group.

The aryl group may be substituted with a phenyl group, a biphenyl group, a terphenyl group, a fluorenyl group, a naphthyl group, a chrysenyl group, a triphenylenyl group, or a phenanthryl group.

The aryl group may have a substituent substituted with an alkyl group containing one to four carbon atoms.

Examples of the alkyl group containing one to four carbon atoms include a methyl group, an ethyl group, a normal propyl group, an isopropyl group, a normal butyl group, an isobutyl group, a secondary butyl group, and a tertiary butyl group.

The skeleton of the condensed polycyclic compound is a structure below, that is, a condensed polycyclic group with high planarity. When a compound having this structure is formed into a thin film, molecules thereof overlap appropriately. When carriers are supplied to this structure, the carriers are likely to hop.

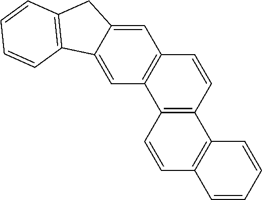 [SMILES: c1ccc2c(c1)Cc1cc3ccc4c5ccccc5ccc4c3cc1-2]

However, this structure is likely to induce intermolecular stacking and is likely to be crystallized.

The condensed polycyclic compound has substituents, represented by X₁ and X₂, having a function for avoiding stacking. Therefore, the molecular stacking of the condensed polycyclic compound is suppressed, the condensed polycyclic compound is unlikely to be crystallized, and an excimer level due to intermolecular association is unlikely to be produced.

The presence of the substituents represented by X₁ and X₂ allows molecules of the condensed polycyclic compound to have an asymmetric structure and is effective in enhancing the above effect.

Thus, the condensed polycyclic compound provides a stable amorphous film which has an appropriate intermolecular stack and high carrier mobility in the form of a thin film and which is unlikely to be crystallized.

The condensed polycyclic compound has a band gap of 2.9 eV to 3.2 eV and a T1 energy of less than 580 nm. These values are suitable as a host material for organic light-emitting elements, particularly as a red phosphorescent host.

Therefore, the condensed polycyclic compound is useful as a host material for organic light-emitting elements. The condensed polycyclic compound has high carrier mobility, forms such a stable amorphous film that is unlikely to be crystallized, and therefore provides an organic light-emitting element having low driving voltage and high durability.

Since the condensed polycyclic compound has a band gap of 2.9 eV to 3.2 eV and a T1 energy of less than 580 nm, the condensed polycyclic compound is useful as a red phosphorescent host material having a band gap suitable for injecting carriers.

The condensed polycyclic compound is difficult to quench singlet and triplet excitons and therefore can be used to provide an organic light-emitting element having low driving voltage and high emission efficiency.

The condensed polycyclic compound is also used as a fluorescent host to provide an organic light-emitting element having low driving voltage and high emission efficiency.

In the condensed polycyclic compound, X₁ or X₂ represents the aryl group. Examples of the aryl group include a phenyl group, a biphenyl group, a terphenyl group, a fluorenyl group, a naphthyl group, a chrysenyl group, a triphenylenyl group, and a phenanthryl group.

The aryl group, which is represented by X₁ or X₂, may be substituted with a phenyl group, a biphenyl group, a terphenyl group, a fluorenyl group, a naphthyl group, a chrysenyl group, a triphenylenyl group, or a phenanthryl group.

The aryl group and the substituent owned by the aryl group have a T1 energy of 500 nm or less. Even if the skeleton of the condensed polycyclic compound is substituted with the substituent, the condensed polycyclic compound has a T1 energy of 580 nm or less.

The substituent reduces the high planarity of the skeleton of the condensed polycyclic compound and has the effect of suppressing crystallization and/or the production of an excimer level due to intermolecular association.

When the aryl group, which is represented by X₁ or X₂, is substituted, the condensed polycyclic compound has a shape close to a linear shape and therefore has high mobility. When the aryl group is represented by X₁ and is substituted, the condensed polycyclic compound keeps amorphousness and has high mobility.

Among the examples of the aryl group, the biphenyl group, the fluorenyl group, and the naphthyl group are preferred. This is because when the condensed polycyclic compound has these groups in the form of substituents, the condensed polycyclic compound has low molecular weight and is highly sublime.

The condensed polycyclic compound, which is represented by Formula (1), may be substituted with an alkyl group containing one to four carbon atoms at any one of R₁ to R₁₄. This leads to an increase in amorphousness and a reduction in ionization potential.

It is preferred that R₁ and R₂ are methyl groups and R₃ to R₁₄ are tertiary butyl groups or isopropyl groups. In particular, R₈ is preferably a tertiary butyl group or an isopropyl group.

Examples of the condensed polycyclic compound are cited below.

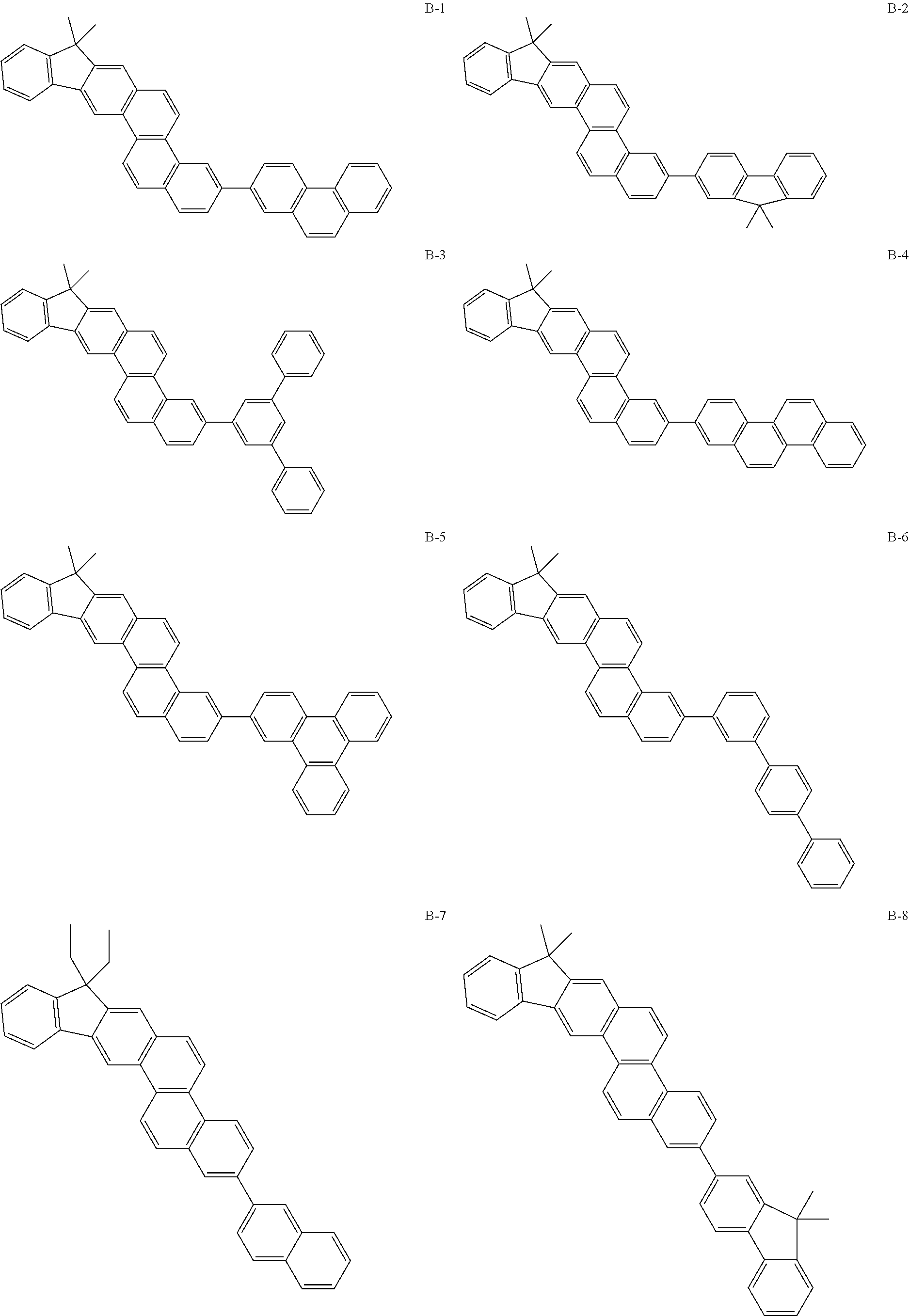

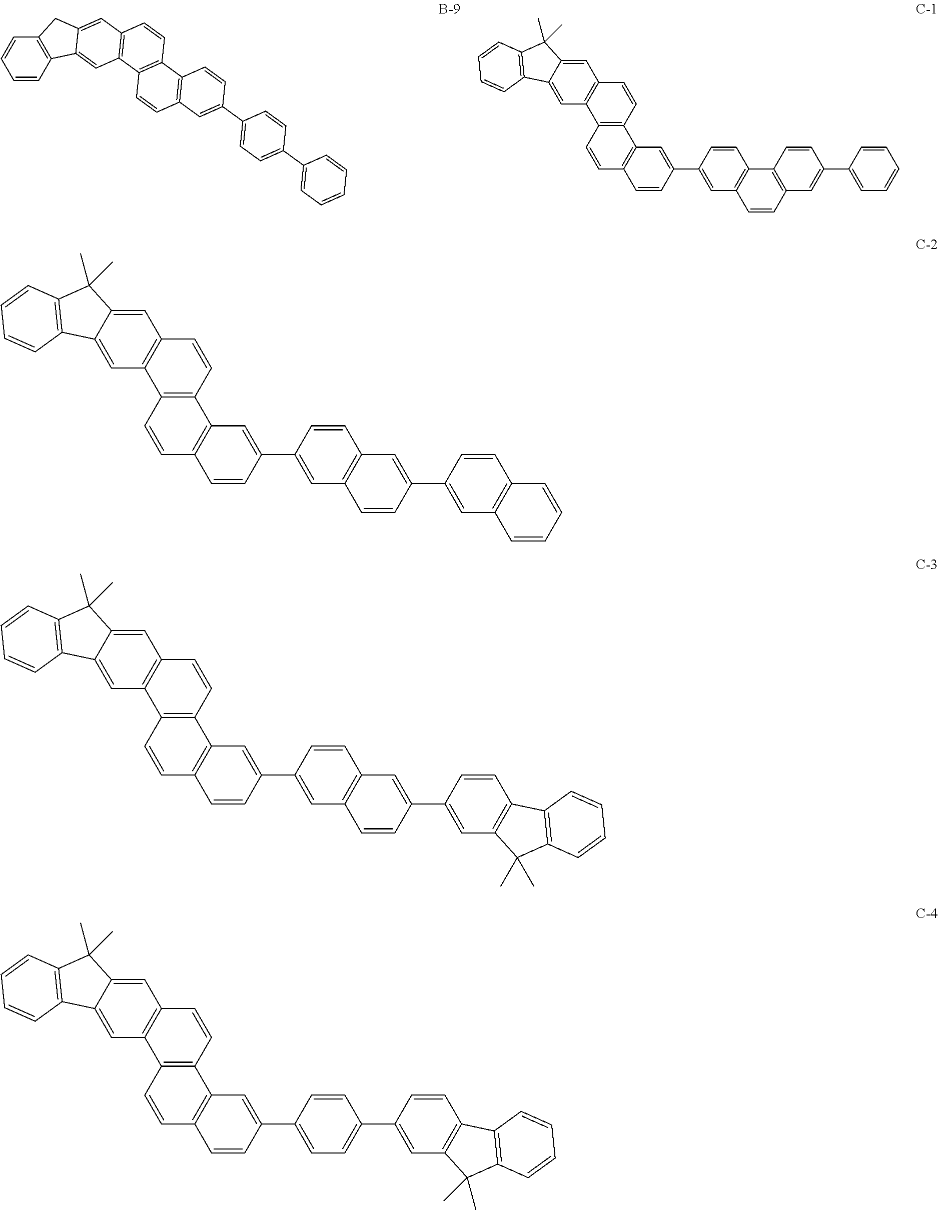

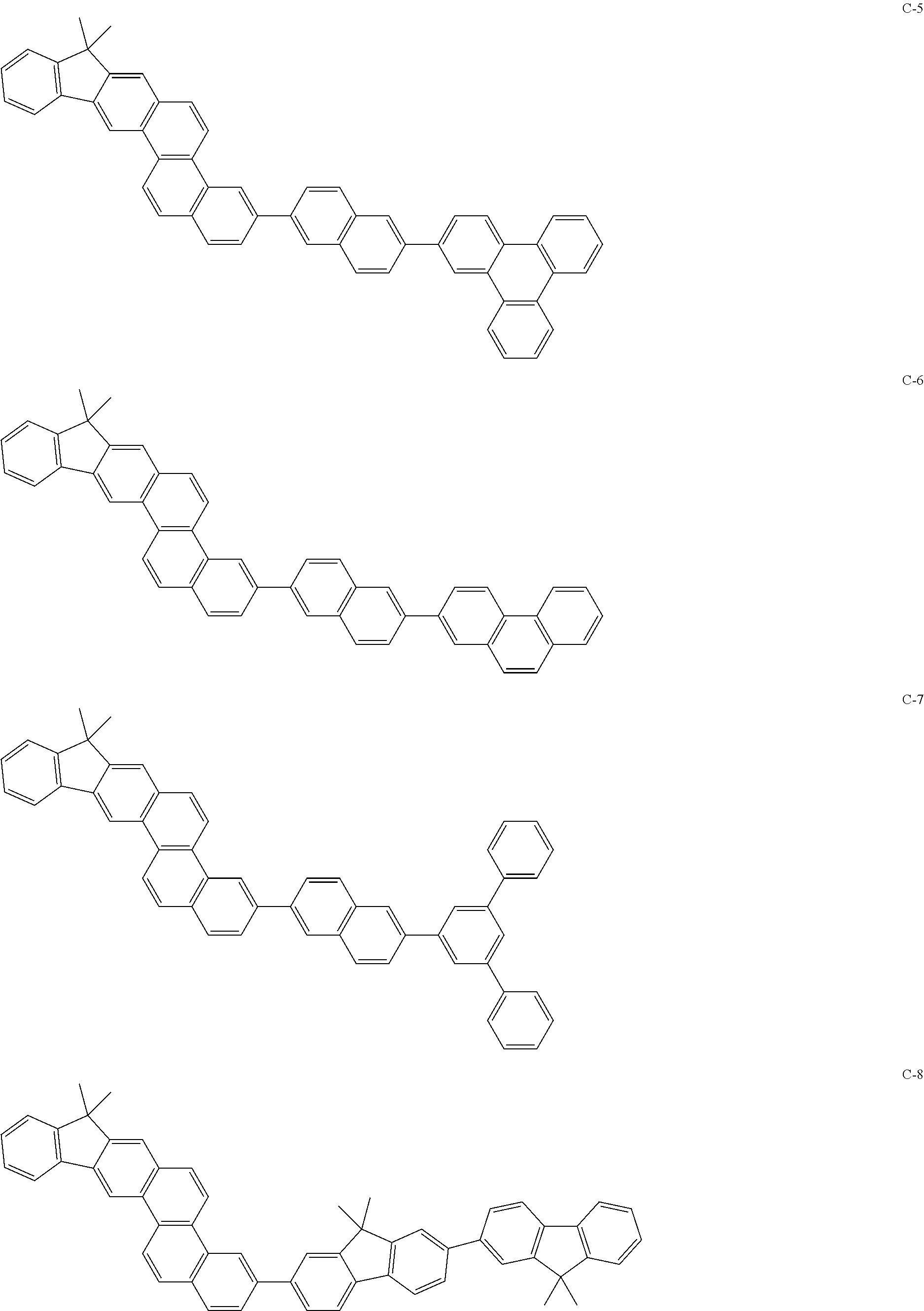

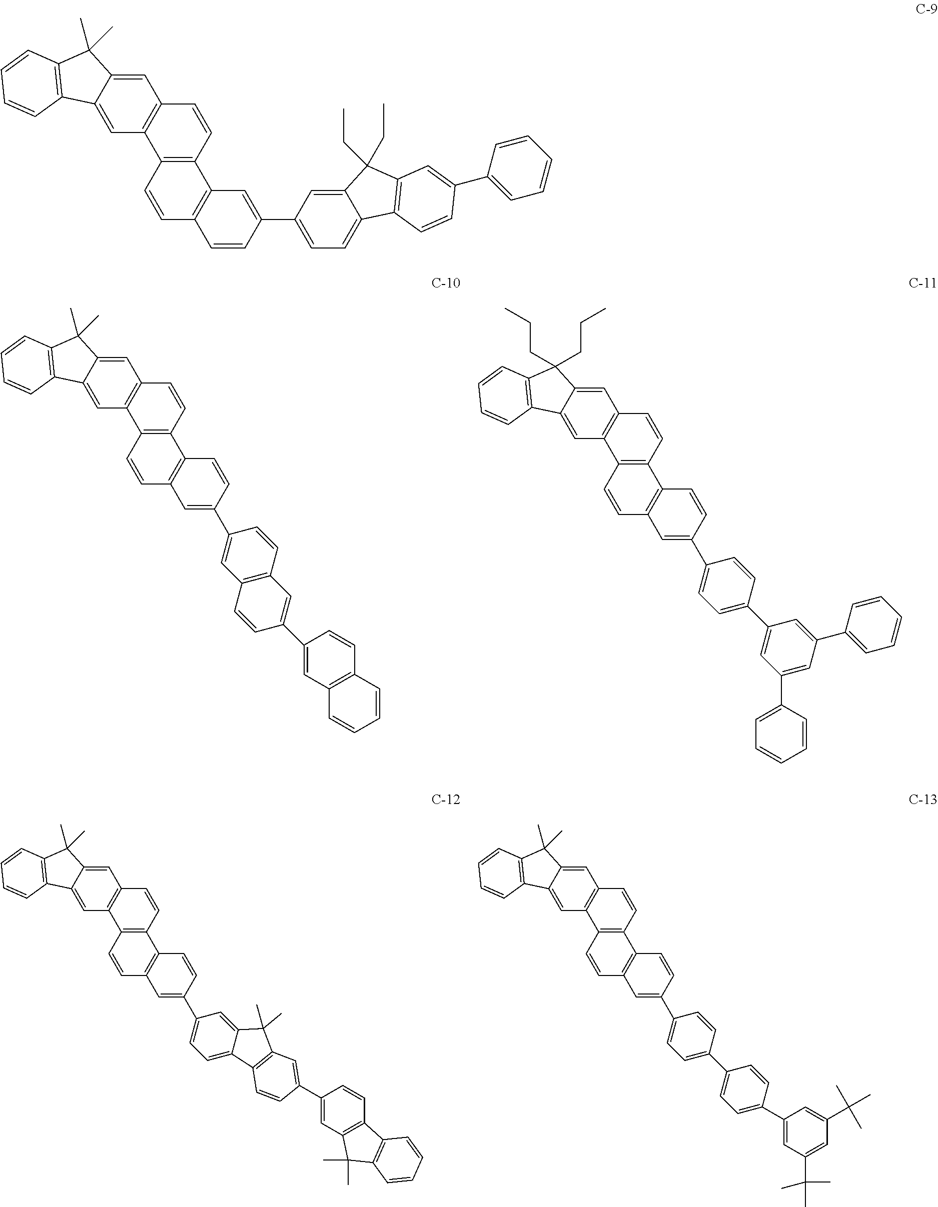

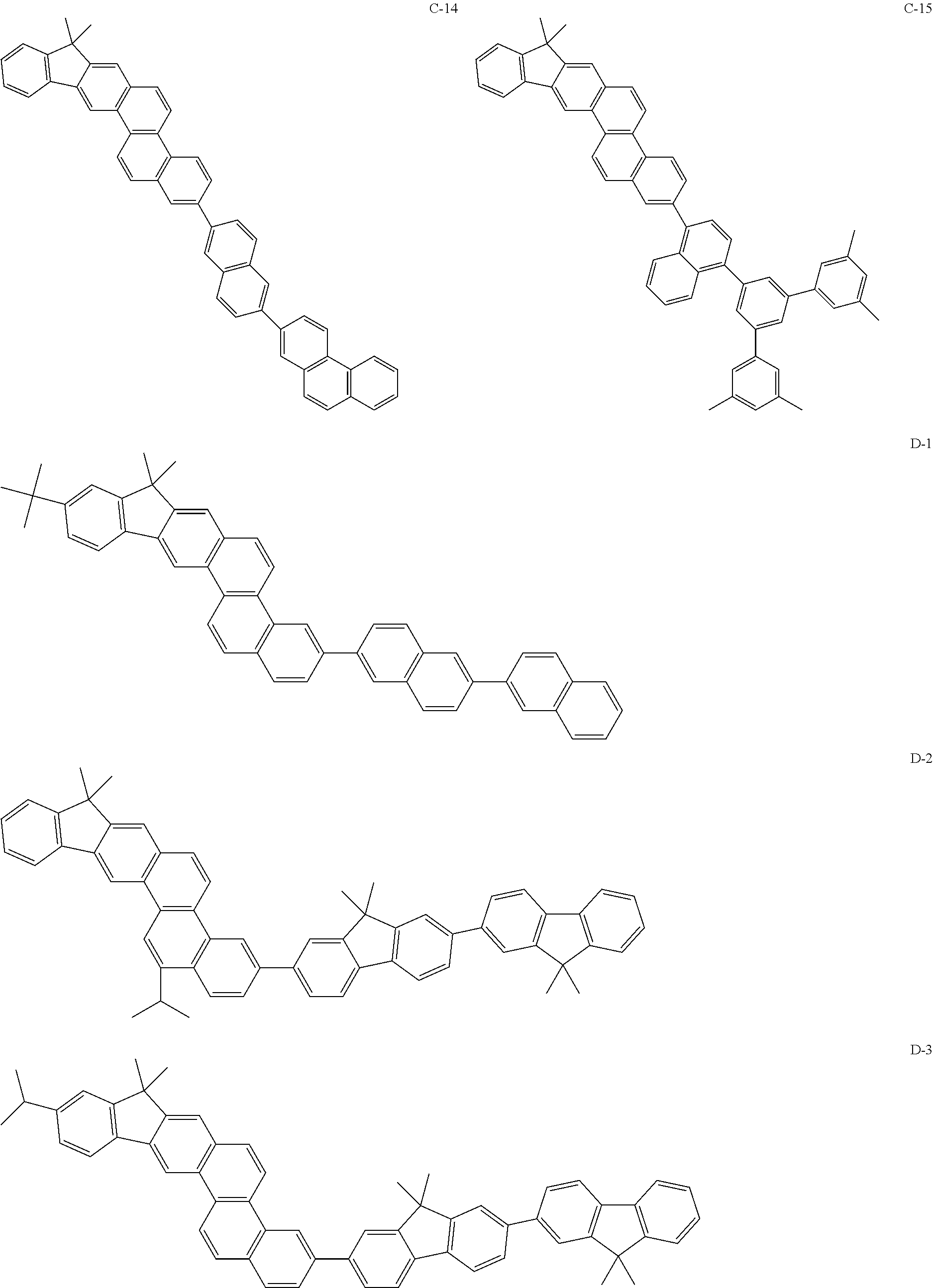

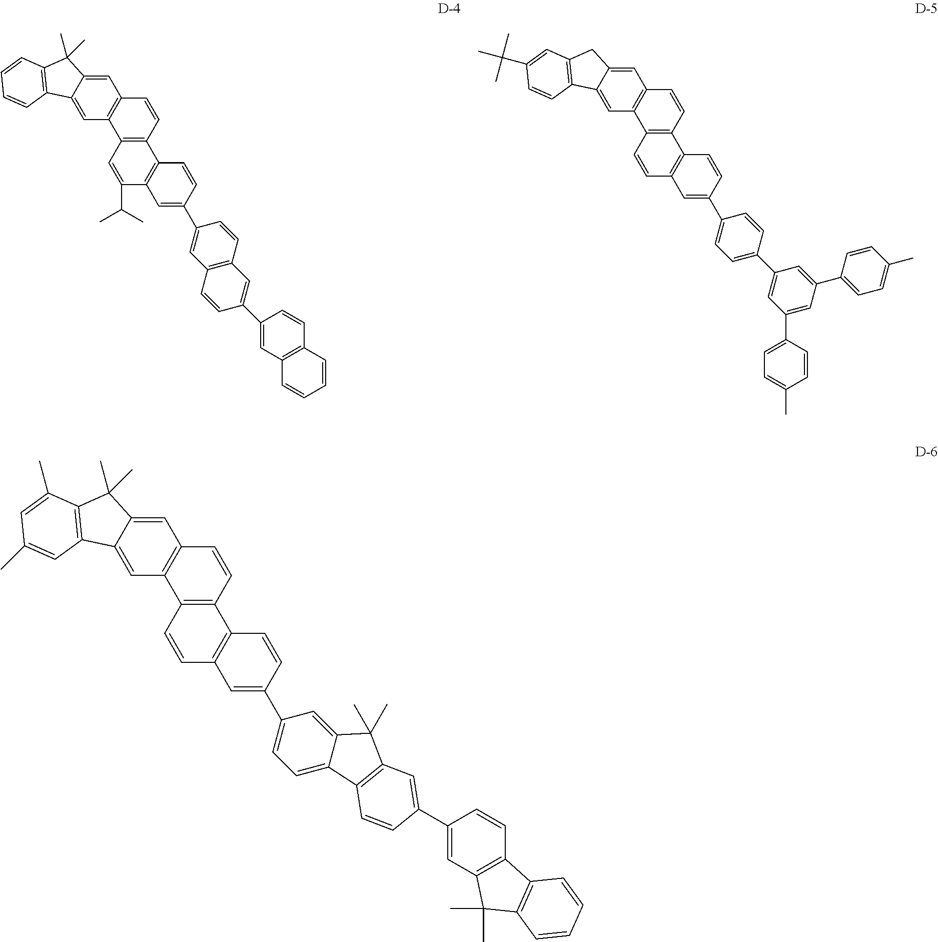

Compounds exemplified in a B-group are a group of compounds in which the aryl group represented by X₂ in Formula (1) is substituted with a substituent. Since these compounds have low molecular weight, these compounds are highly sublime and therefore sublimate at low temperature.

Compounds exemplified in a C-group are a group of compounds in which the aryl group represented by X₂ in Formula (1) includes two aryl moieties.

The compounds exemplified in the C-group each form a stable amorphous film and have increased mobility. An alkyl group, such as a methyl group or a tertiary butyl group, bonded to the aryl group can reduce the ionization potential of these compounds.

Compounds exemplified in a D-group are a group of compounds in which the skeleton of the condensed polycyclic compound is substituted with an alkyl group containing one to four carbon atoms. This alkyl group can increase the amorphousness of these compounds and can reduce the ionization potential of these compounds.

Compounds, like the compounds exemplified in the C-group, containing an aryl group substituted with two moieties have the effect of increasing sublimation and therefore are useful. For more preferred substituents, R₁ and R₂ are methyl groups and R₃ to R₁₄ are tertiary butyl groups and isopropyl groups.

Compounds B-1 to B-6, C-1 to C-9, and D-1 to D-3 exemplified above are those in which X₁ in Formula (1) is an aryl group. These compounds keep amorphousness and have higher mobility as compared to those in which X₂ in Formula (1) is an aryl group.

An organic light-emitting element according to an embodiment of the present invention will now be described.

The organic light-emitting element includes a pair of electrodes, that is, an anode and a cathode and also includes an organic compound layer placed therebetween. The organic compound layer contains the condensed polycyclic compound, which is represented by Formula (1). The organic light-emitting element is an organic electrochromic element in which an organic compound emits light when holes and electrons are separated from two electrodes.

The organic compound layer, which is included in the organic light-emitting element, may be one of organic compound layers. Such organic compound layers are a hole injection layer, a hole transport layer, a light-emitting layer, an electron transport layer, an electron injection layer, and the like, these layers being stacked. The organic light-emitting element may further include another layer in addition to the above layers depending on purposes thereof.

Examples of the configuration of the organic light-emitting element include a configuration in which the anode, a light-emitting layer, and the cathode are placed on a substrate in that order; a configuration in which the anode, a hole transport layer, an electron transport layer, and the cathode are placed on a substrate in that order; a configuration in which the anode, a hole transport layer, a light-emitting layer, an electron transport layer, and the cathode are placed on a substrate in that order; a configuration in which the anode, a hole injection layer, a hole transport layer, a light-emitting layer, an electron transport layer, and the cathode are placed on a substrate in that order; and a configuration in which the anode, a hole transport layer, a light-emitting layer, a hole/exciton-blocking layer, an electron transport layer, and the cathode are placed on a substrate in that order.

Besides these five multilayer configurations, the organic light-emitting element may have substantially the same configuration as one of these five multilayer configurations except that an electrode located close to a substrate is a cathode and the order of layers is reversed.

The organic compound layer, which contains the condensed polycyclic compound, is preferably a light-emitting layer. The light-emitting layer contains a host material and a guest material. The condensed polycyclic compound is preferably the host material.

The host material is a compound having the highest weight proportion in the light-emitting layer. The guest material is a compound which is less in weight proportion than the host material and which predominantly emits light. An assist material is contained in the light-emitting layer, is less in weight proportion than the host material, and assists the guest material to emit light.

The guest material is also referred to as a dopant material. The assist material is also referred to as a second host material.

The content of the host material in the light-emitting layer is preferably 0.1% to 30% by mass and more preferably 0.5% to 10% by mass.

The organic light-emitting element may contain various low- and high-molecular weight hole injection materials, hole transport materials, host materials, guest materials, electron injection materials, electron transport materials, and the like in combination as required in addition to the condensed polycyclic compound.

A hole injection or transport material used preferably has high hole mobility. Examples of low- and high-molecular weight materials having a hole injection or transport ability include, but are not limited to, triarylamine derivatives, phenylenediamine derivatives, stilbene derivatives, phthalocyanine derivatives, porphyrin derivatives, polyvinylcarbazole, polythiophene, and other conductive polymers.

Examples of the host material include, but are not limited to, triarylamine derivatives; phenylene derivatives; condensed aromatic compounds such as naphthalene derivatives, phenanthrene derivatives, fluorene derivatives, and chrysene derivatives; organometallic complexes such as organoaluminum complexes including tris(8-quinolinolato) aluminum, organoberyllium complexes, organoiridium complexes, and organoplatinum complexes; and polymeric derivatives such as poly(phenylene vinylene) derivatives, polyfluorene derivatives, polyphenylene derivatives, poly(thienylene vinylene) derivatives, and polyacetylene derivatives.

Examples of the guest material include fluorescent iridium complexes and platinum complexes. The guest material may be fluorescent. In particular, the guest material preferably emits red phosphorescent light. Examples of an iridium complex used as a phosphorescent material in the present invention are described below. The present invention is not limited to these examples.

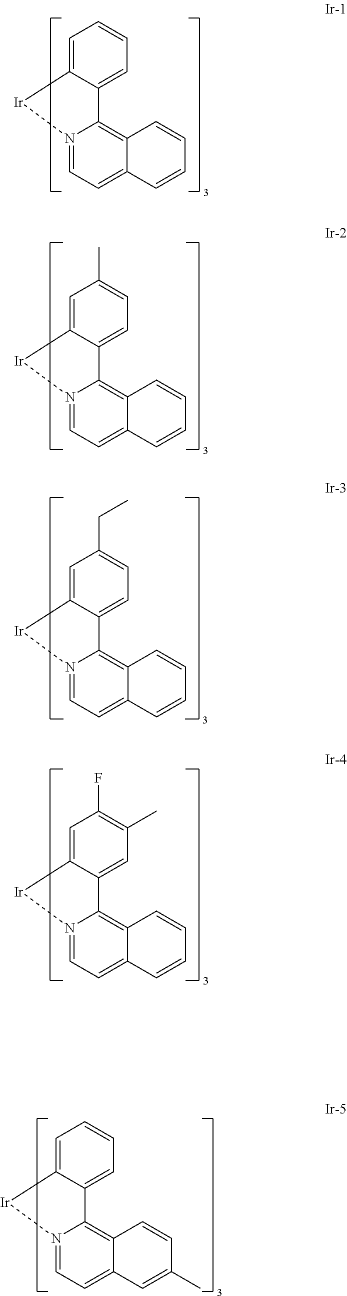

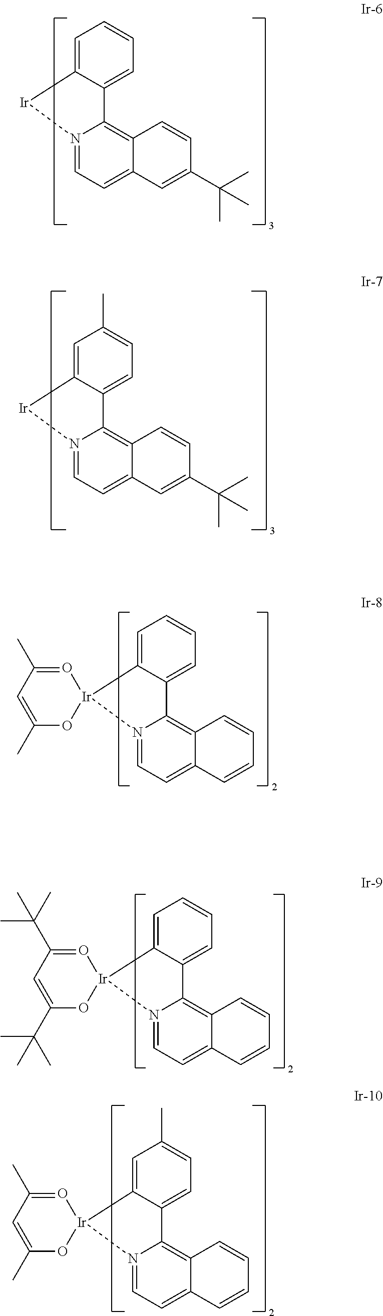

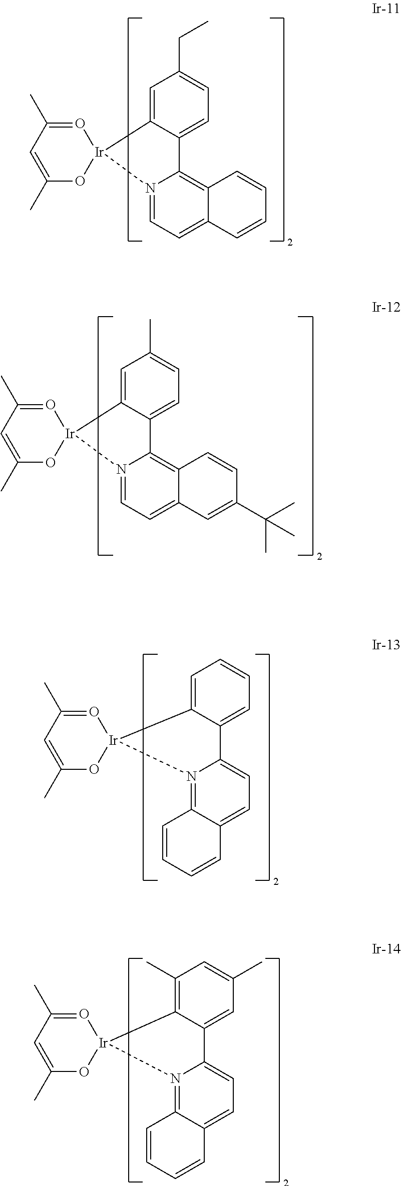

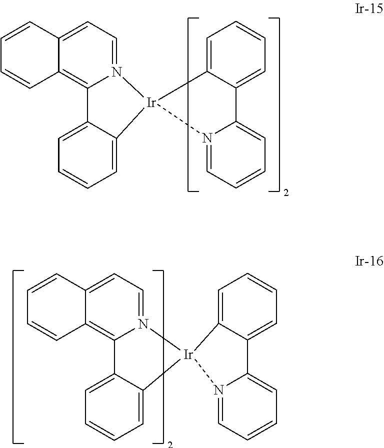

An electron injection or transport material used is selected in consideration of the balance with the hole mobility of the hole injection or transport material. Examples of a material having an electron injection or transport ability include, but are not limited to, oxadiazole derivatives, oxazole derivatives, pyrazine derivatives, triazole derivatives, triazine derivatives, quinoline derivatives, quinoxaline derivatives, phenanthroline derivatives, and organoaluminum complexes.

An anode material used preferably has a large work function. Examples of the anode material include metals such as gold, platinum, silver, copper, nickel, palladium, cobalt, selenium, vanadium, and tungsten; alloys of these metals; and metal oxides such as tin oxide, zinc oxide, indium oxide, indium tin oxide (ITO), and indium zinc oxide. The anode material may be a conductive polymer such as polyaniline, polypyrrole, or ploythiophene. These materials may be used alone or in combination. The anode may have a single-layer structure or a multilayer structure.

A cathode material used preferably has a small work function. Examples of the cathode material include alkali metals such as lithium; alkaline-earth metals such as calcium; metals such as aluminum, titanium, manganese, silver, lead, and chromium; and alloys of these metals

For example, magnesium-silver, aluminum-lithium, aluminum-magnesium, and the like can be used. A metal oxide such as indium tin oxide (ITO) can be used. These materials may be used alone or in combination. The cathode may have a single-layer structure or a multilayer structure.

In the organic light-emitting element, the organic compound layer, which contains the condensed polycyclic compound, and layers containing other organic compounds are formed by a process below. In general, the following process is used: a vacuum vapor deposition process, an ionization vapor deposition process, a sputtering process, a plasma process, or a known coating process, such as a spin coating process, a dipping process, a casting process, a Langmuir-Blodgett (LB) process, or an ink jet process, using an appropriate solvent. In the case of forming a layer by the vacuum vapor deposition process or the coating process, the layer is unlikely to be crystallized and has good temporal stability. In the case of forming a film by the coating process, an appropriate binder resin can be used in combination with another material.

Examples of the binder resin include, but are not limited to, polyvinylcarbazole, polycarbonate, polyester, acrylonitrile-butadiene-styrene (ABS) resins, acrylic resins, polyimide, phenol resins, epoxy resins, silicone resins, and urea resins. These resins may be used alone in the form of a homopolymer or a copolymer or in combination. The binder resin may be used in combination with a known additive such as a plasticizer, an oxidation inhibitor, or an ultraviolet absorber as required.

Applications of the organic light-emitting element are described below. The organic light-emitting element can be used as a component of a display device or a lighting device. In addition, the organic light-emitting element has applications such as an exposure light source for electrophotographic image-forming devices, a backlight for liquid crystal display devices, and a light. The organic light-emitting element may include a color filter.

A display device according to an embodiment of the present invention includes a display section including a plurality of pixels including organic light-emitting elements identical to the organic light-emitting element.

The pixels include the organic light-emitting element and active elements. An example of the active element is a switching element. An example of the switching element is a thin-film transistor (TFT).

The anode or cathode of the organic light-emitting element is connected to a drain or source electrode, respectively, of the TFT. The display device can be used as an image display device for personal computers (PCs). The TFT is placed on an insulating surface of a substrate.

The display device includes an input section supplied with image information from an area charge-coupled device (CCD), a linear CCD, or a memory card and may be an image information processor including a display section for displaying an input image.

The display section, which is included in the image information processor or the display device, may have a touch panel function. The display device may be used in a display section of a multifunction printer.

The lighting device is a device lighting, for example, a room. The lighting device may emit white light, neutral white light, or light with a wavelength corresponding to blue or red.

When the lighting device includes the organic light-emitting element, the organic light-emitting element includes organic compound layers, particularly light-emitting layers containing a plurality of luminescent materials. At least some of the luminescent materials emit light of a color different from the color of light emitted from the other luminescent materials, whereby lighting light is obtained. Lighting light is preferably white.

The luminescent materials may be contained in one of the light-emitting layers or may be separately contained in the light-emitting layers. When the luminescent materials are separately contained in the light-emitting layers, the light-emitting layers may be stacked or may be horizontally arranged.

The term “horizontally arranged” as used herein means that the light-emitting layers are each in contact with an adjacent layer such as a hole transport layer or an electron transport layer.

The lighting device includes the organic light-emitting element and an AC/DC converter circuit connected thereto. The lighting device may further include a color filter.

The AC/DC converter circuit is a circuit which converts an alternating-current voltage into a direct-current voltage and which is used to supply a driving voltage to the organic light-emitting element.

An image-forming device according to an embodiment of the present invention includes a photoreceptor, an electrifying section electrifying a surface of the photoreceptor, an exposure section for exposing the photoreceptor to light, and a developing unit for developing an electrostatic latent image formed on the photoreceptor. The exposure section includes the organic light-emitting element.

The exposure section is, for example, an exposure device including organic light-emitting elements identical to the organic light-emitting element. The organic light-emitting elements included in the exposure device may be arranged in a line or may be arranged such that the whole of an exposure surface of the exposure device emits light.

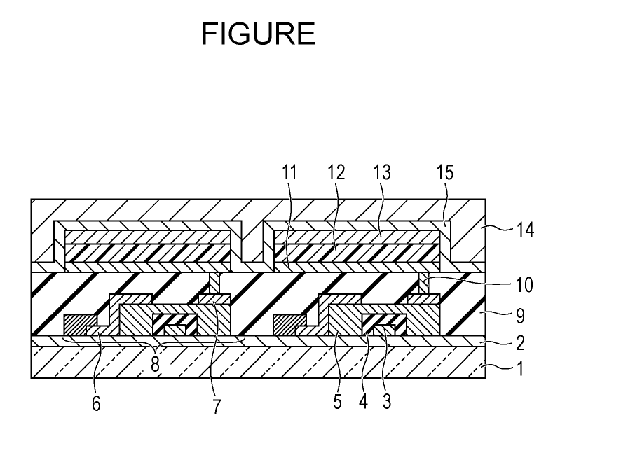

The display device, which includes the organic light-emitting element, is described below with reference to FIG. 1.

FIG. 1 is a schematic sectional view of the display device. The display device includes the organic light-emitting element and a TFT which is connected to the organic light-emitting element and which is an example of a switching element. FIG. 1 illustrates two organic light-emitting elements and two TFTs 8 paired therewith. The configuration of the display device is described below in detail.

The display device includes a substrate 1 such as a glass substrate and a moisture barrier film 2, placed thereon, for protecting the organic light-emitting elements and the TFTs 8. Reference numeral 3 represents gate electrodes made of metal, reference numeral 4 represents gate insulating films, and reference numeral 5 represents semiconductor layers.

Each of the TFTs 8 includes a corresponding one of the semiconductor layers 5, a drain electrode 6, and a source electrode 7. The TFTs 8 are overlaid with an insulating film 9. Each of the organic light-emitting elements includes an anode 11, an organic compound layer 12, and a cathode 13. The anode 11 is connected to one of the source electrodes 7 through a contact hole 10. The display device is not limited to this configuration. One of the anode 11 and cathode 13 of each organic light-emitting element may be connected to either one of the source electrode 7 and drain electrode 6 of a corresponding one of the TFTs 8.

The organic compound layer 12 has a multilayer structure and is illustrated in the form of a single layer in FIG. 1. The cathodes 13 are overlaid with a first protective film 14 and second protective film 15 for suppressing the deterioration of the organic light-emitting elements.

The display device may include metal-insulator-metal (MIM) elements serving as switching elements instead of the TFTs 8.

The organic light-emitting elements include active elements. The active elements may be formed directly in a substrate such as a Si substrate. The expression “formed directly in a substrate” as used herein means that a substrate such as a Si substrate is processed so as to have transistors.

These components are selected depending on resolution. In the case of, for example, a resolution of about quarter video graphics array (QVGA) per inch, the active elements are preferably provided directly in a Si substrate. The active elements are preferably transistors.

A good quality image can be stably displayed for a long time by driving the display device, which includes the organic light-emitting element. The condensed polycyclic compound can be used not only in the organic light-emitting element but also for in-vivo labeling and in filter films.

### EXAMPLES

Examples are described below. The present invention is not limited to the examples.

### Example 1

Compound C-8 exemplified above was synthesized as described below. First, Compound a-2 was synthesized by the following reaction:

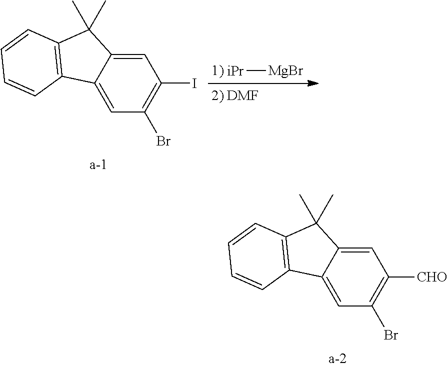

In particular, 2.0 g (5.0 mmol) of Compound a-1 and 40 ml of dehydrated tetrahydrofuran (THF) were put in a 100 ml three-necked flask. To the flask, 7.0 ml of a 1 M THF solution of isopropylmagnesium bromide was added dropwise at −40° C., followed by stirring at −40° C. for one hour.

Thereafter, 1.05 g (15.0 mmol) of dehydrated dimethylformamide (DMF) was added dropwise to the flask, followed by stirring at 0° C. for two hours. After the reaction was completed, 100 ml of water was added to the flask and an organic layer was extracted with toluene, was dried with sodium sulfate anhydride, and was then purified with a silica gel column using a toluene-heptane mixture as a developing solvent, whereby 1.10 g of Compound a-2 (white crystals) was obtained (a yield of 73%).

Compound a-4 was synthesized by the following reaction:

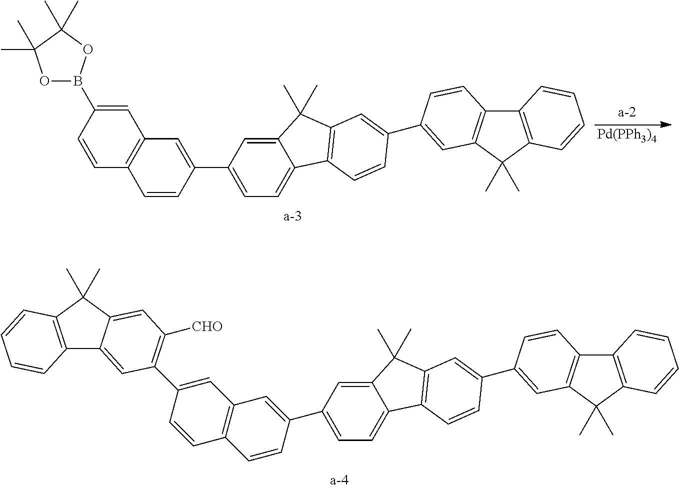 [SMILES: CC1(C)c2ccccc2-c2ccc(-c3ccc4c(c3)C(C)(C)c3cc(-c5ccc6ccc(B7OC(C)(C)C(C)(C)O7)cc6c5)ccc3-4)cc21 ; CC1(C)c2ccccc2-c2ccc(-c3ccc4c(c3)C(C)(C)c3cc(-c5ccc6ccc(-c7cc8c(cc7C=O)C(C)(C)c7ccccc7-8)cc6c5)ccc3-4)cc21 ; "Pd(PPh3)4"]

In particular, the following compounds were put in a 100 ml three-necked flask: 0.510 g (1.7 mmol) of Compound a-2, 1.17 g (1.83 mmol) of Compound a-3, 5 g of sodium carbonate, 20 ml of toluene, 10 ml of ethanol, and ml of water. To the flask, 106 mg of tetrakis(triphenylphosphine) palladium (0) was added under stirring at room temperature in a nitrogen atmosphere, followed by heating to 80° C. and stirring for five hours.

After the reaction was completed, an organic layer was extracted with toluene, was dried with sodium sulfate anhydride, and was then purified with a silica gel column using a toluene-heptane mixture as a developing solvent, whereby 1.21 g of Compound a-4 (white crystals) was obtained (a yield of 97%).

Compound a-6 was synthesized by the following reaction:

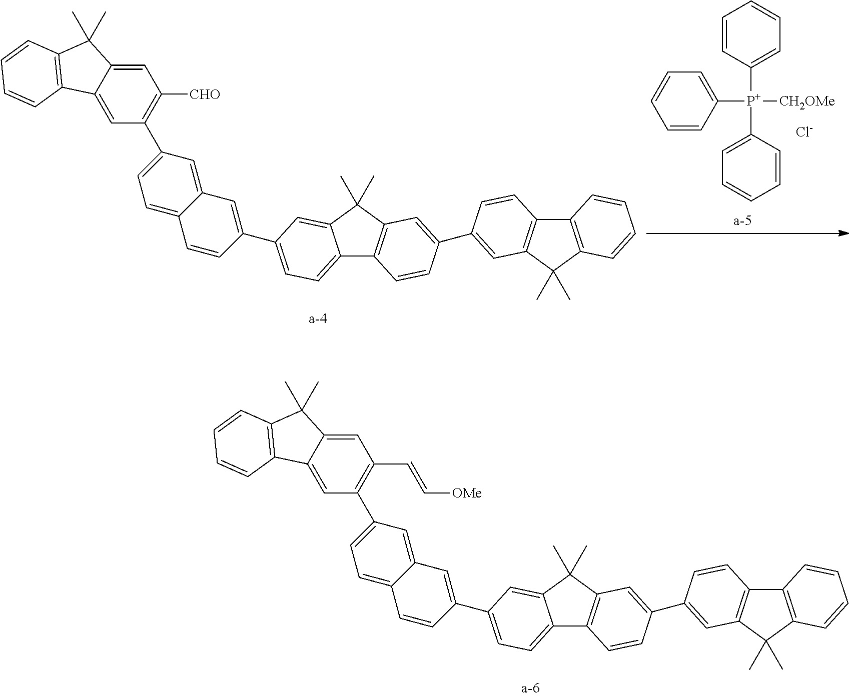

In particular, the following compounds were put in a 100 ml three-necked flask: 1.42 g (4.13 mmol) of Compound a-5, 0.463 g (4.13 mmol) of potassium t-butoxide (t-BuOK), and 40 ml of dehydrated THF. To the flask, 1.21 g (1.65 mmol) of Compound a-4 was added little by little at 0° C., followed by stirring at 0° C. for five hours. After the reaction was completed, 100 ml of water was added to the flask and an organic layer was extracted with toluene, was dried with sodium sulfate anhydride, and was then purified with a silica gel column using a toluene-heptane mixture as a developing solvent, whereby 1.15 g of Compound a-6 (white crystals) was obtained (a yield of 92%).

Compound C-8 was synthesized by the following reaction:

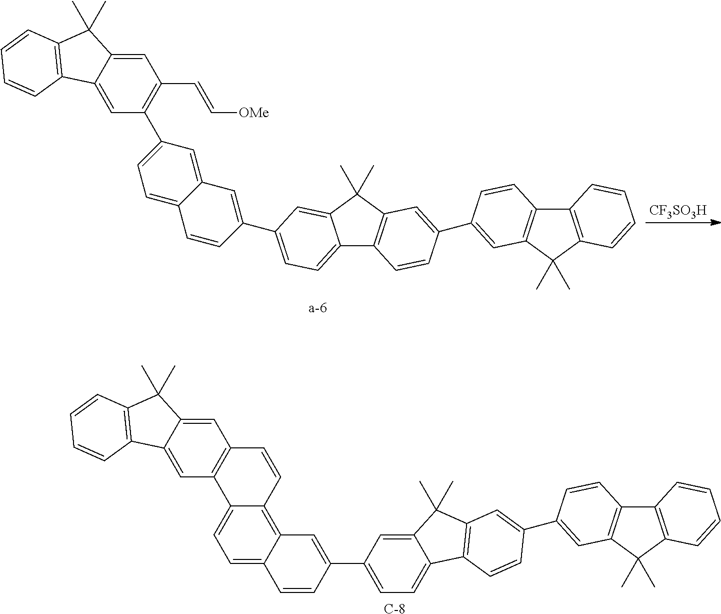

In particular, 1.0 g (1.31 mmol) of Compound a-6 and 30 ml of dehydrated methylene chloride were put in a 100 ml three-necked flask. To the flask, 0.085 ml (1.31 mmol) of trifluoromethanesulfonic acid was added at room temperature, followed by stirring for three hours.

After the reaction was completed, 20 ml of water was added to the flask and an organic layer was extracted with chloroform, was dried with sodium sulfate anhydride, and was then purified with a silica gel column using a toluene-heptane mixture as a developing solvent, whereby 0.728 g of Compound C-8 (white crystals) was obtained (a yield of 76%).

A peak corresponding to a molecular ion (M⁺) of Compound C-8 was observed at an m/z value of 728 by mass spectroscopy.

The structure of Compound C-8 was determined by ¹H nuclear magnetic resonance (NMR) analysis.

¹H NMR (CDCl₃, 400 MHz) σ (ppm): 9.13 (s, 1H), 9.05 (s, 1H), 8.89-8.82 (m, 2H), 8.12-8.01 (m, 5H), 7.97 (d, 1H), 7.93-7.81 (m, 5H), 7.78-7.66 (m, 5H), 7.52 (d, 1H), 7.48-7.44 (m, 5H), 1.70 (s, 6H), 1.65 (s, 6H), 1.59 (s, 6H)

The band gap of Compound C-8 was 2.99 eV. The T1 energy of Compound C-8 was 534 nm.

The band gap can be determined from a visible-ultraviolet absorption spectrum. In this example, a film was formed on a glass substrate by a spin coating process using a 0.1% chloroform solution of Compound C-8 and the band gap of Compound C-8 was determined from the absorption edge of the film. An instrument used was a spectrometer, U-3010, available from Hitachi, Ltd.

The T1 energy of Compound C-8 was determined as follows: a 1×10⁻⁴ mol/l toluene solution of Compound C-8 was cooled to 77 K, a phosphorescent component was measured at an excitation wavelength of 350 nm, and a first emission peak was used to determine the T1 energy thereof. An instrument used was a spectrometer, U-3010, available from Hitachi, Ltd.

### Example 2

Compound B-1 exemplified above was synthesized in substantially the same way as that described in Example 1 except that Compound a-7 below was used instead of Compound a-3. A peak corresponding to a molecular ion (M⁺) of Compound B-1 was observed at an m/z value of 521 by mass spectroscopy. The band gap of a film formed from Compound B-1 by spin coating was 3.05 eV. The T1 energy of Compound B-1 was 530 nm.

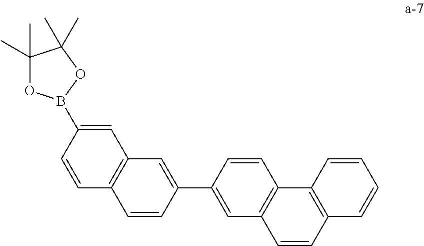 [SMILES: CC1(C)OB(c2ccc3ccc(-c4ccc5c(ccc6ccccc65)c4)cc3c2)OC1(C)C]

### Example 3

Compound B-4 exemplified above was synthesized in substantially the same way as that described in Example 1 except that Compound a-8 below was used instead of Compound a-3. A peak corresponding to a molecular ion (M⁺) of Compound B-4 was observed at an m/z value of 570 by mass spectroscopy. The band gap of a film formed from Compound B-4 by spin coating was 2.98 eV. The T1 energy of Compound B-4 was 538 nm.

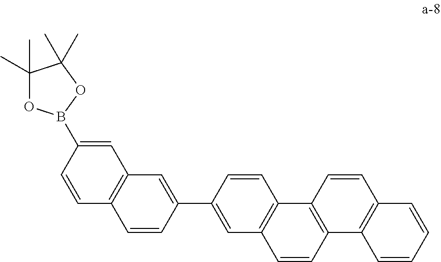 [SMILES: CC1(C)OB(c2ccc3ccc(-c4ccc5c(ccc6c7ccccc7ccc56)c4)cc3c2)OC1(C)C]

### Example 4

Compound B-8 exemplified above was synthesized in substantially the same way as that described in Example 1 except that Compound a-9 below was used instead of Compound a-3. A peak corresponding to a molecular ion (M⁺) of Compound B-8 was observed at an m/z value of 536 by mass spectroscopy.

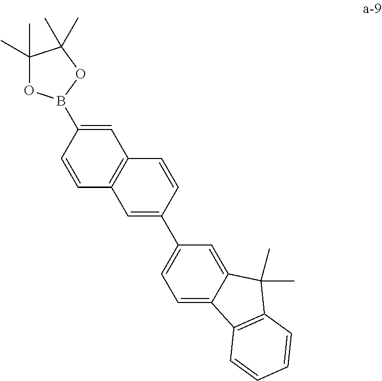

### Example 5

Compound C-2 exemplified above was synthesized in substantially the same way as that described in Example 1 except that Compound a-10 below was used instead of Compound a-3. A peak corresponding to a molecular ion (M⁺) of Compound C-2 was observed at an m/z value of 597 by mass spectroscopy.

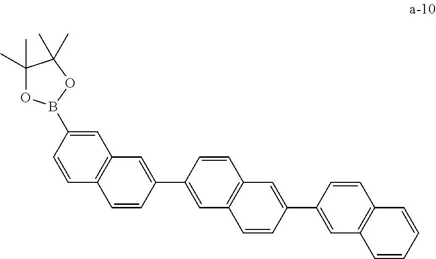 [SMILES: CC1(C)OB(c2ccc3ccc(-c4ccc5cc(-c6ccc7ccccc7c6)ccc5c4)cc3c2)OC1(C)C]

### Example 6

Compound C-3 exemplified above was synthesized in substantially the same way as that described in Example 1 except that Compound a-11 below was used instead of Compound a-3. A peak corresponding to a molecular ion (M⁺) of Compound C-3 was observed at an m/z value of 663 by mass spectroscopy.

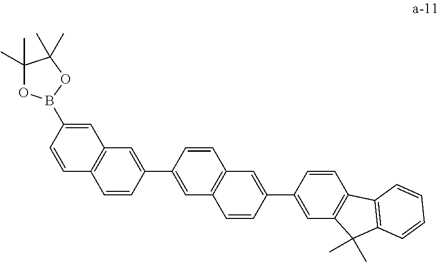 [SMILES: CC1(C)c2ccccc2-c2ccc(-c3ccc4cc(-c5ccc6ccc(B7OC(C)(C)C(C)(C)O7)cc6c5)ccc4c3)cc21]

### Example 7

Compound C-5 exemplified above was synthesized in substantially the same way as that described in Example 1 except that Compound a-12 below was used instead of Compound a-3.

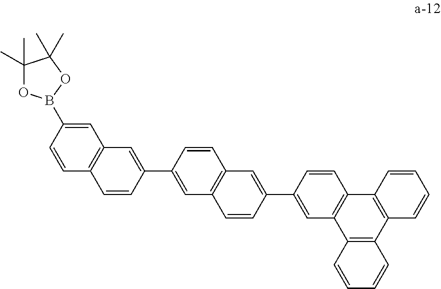 [SMILES: CC1(C)OB(c2ccc3ccc(-c4ccc5cc(-c6ccc7c8ccccc8c8ccccc8c7c6)ccc5c4)cc3c2)OC1(C)C]

A peak corresponding to a molecular ion (M⁺) of Compound C-5 was observed at an m/z value of 697 by mass spectroscopy.

### Example 8

In this example, an organic light-emitting element was prepared.

A transparent conductive support substrate was prepared in such a way that an anode was formed on a glass base plate by a sputtering process using indium tin oxide (ITO) so as to have a thickness of 120 nm.

The transparent conductive support substrate was ultrasonically cleaned with acetone and isopropyl alcohol (IPA) in that order, was cleaned with boiling IPA, was dried, and was then subjected to UV-ozone cleaning.

Organic layers and electrode layers below were continuously formed on the transparent conductive support substrate in a 10⁻⁵ Pa vacuum chamber by vacuum vapor deposition using resistive heating, whereby the organic light-emitting element was prepared.

A hole transport layer, having a thickness of 40 nm, containing Compound c-1.
An electron-blocking layer, having a thickness of 10 nm, containing Compound c-2.
A light-emitting layer, having a thickness of 30 nm, containing Compound c-3 and Compound C-8, Compound c-3 serving as a guest material, Compound C-8 serving as a host material, the content of Compound c-3 in the light-emitting layer being 4% by weight, the content of Compound C-8 in the light-emitting layer being 96% by weight.
A hole-blocking layer, having a thickness of 10 nm, containing Compound c-4.
An electron transport layer, having a thickness of 50 nm, containing Compound c-5.
A metal electrode layer 1, having a thickness of 0.5 nm, containing lithium fluoride (LiF).

A metal electrode layer 2, having a thickness of 150 nm, containing aluminum (Al).

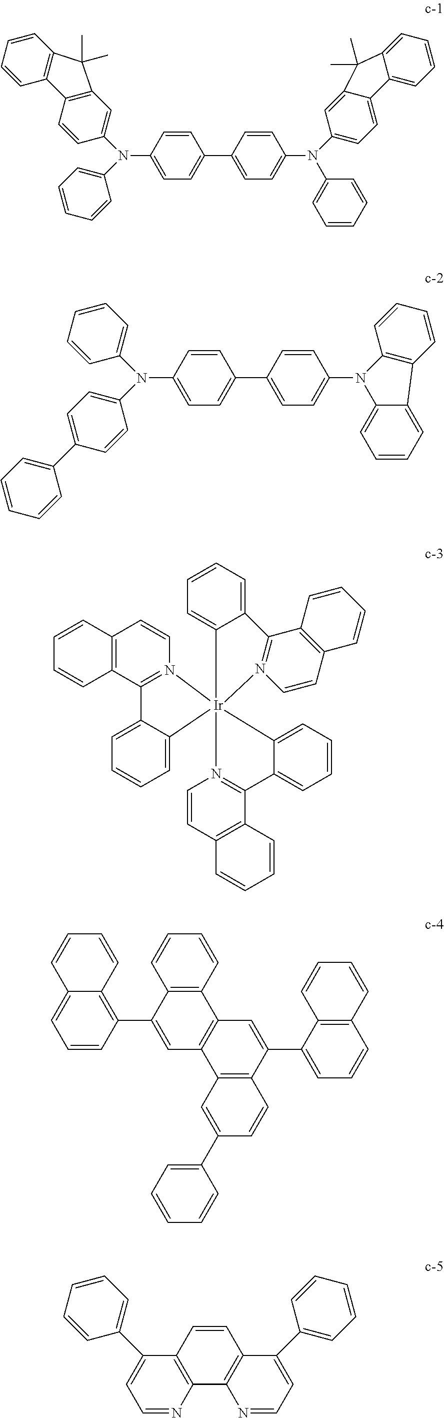

When a voltage of 5.0 V was applied to the organic light-emitting element, good red emission with CIE chromaticity coordinates (0.32, 0.68) was observed at a luminance of 1,730 cd/m².

Furthermore, a voltage was continuously applied to the organic light-emitting element for 100 hours in a nitrogen atmosphere such that the current density was maintained at 100 mA/cm². As a result, the luminance of the organic light-emitting element operated for 400 hours was 20% or less of the initial luminance thereof, that is, the rate of deterioration in luminance of the organic light-emitting element was small.

### Example 9

An organic light-emitting element was prepared in substantially the same way as that described in Example 8 except that Compound C-2 was used instead of Compound C-8.

When a voltage of 5.0 V was applied to the organic light-emitting element, good red emission with CIE chromaticity coordinates (0.32, 0.68) was observed at a luminance of 1,690 cd/m².

Furthermore, a voltage was continuously applied to the organic light-emitting element for 100 hours in a nitrogen atmosphere such that the current density was maintained at 100 mA/cm². As a result, the luminance of the organic light-emitting element operated for 400 hours was 30% or less of the initial luminance thereof, that is, the rate of deterioration in luminance of the organic light-emitting element was small.

### Example 10

An organic light-emitting element was prepared in substantially the same way as that described in Example 8 except that Compound C-3 was used instead of Compound C-8.

When a voltage of 5.0 V was applied to the organic light-emitting element, good red emission with CIE chromaticity coordinates (0.32, 0.68) was observed at a luminance of 1,720 cd/m².

Furthermore, a voltage was continuously applied to the organic light-emitting element for 100 hours in a nitrogen atmosphere such that the current density was maintained at 100 mA/cm². As a result, the luminance of the organic light-emitting element operated for 400 hours was 30% or less of the initial luminance thereof, that is, the rate of deterioration in luminance of the organic light-emitting element was small.

The present invention has been described with reference to embodiments and examples. According to the present invention, a novel condensed polycyclic compound having a band gap and T1 energy (lowest excited triplet energy) suitable as a red phosphorescent host can be provided. Furthermore, the following element can be provided: an organic light-emitting element which contains the condensed polycyclic compound and which has high efficiency, a high light output, and high durability.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-232176 filed Oct. 19, 2012, which is hereby incorporated by reference herein in its entirety.

What is claimed is:

1. A condensed polycyclic compound represented by the following formula: 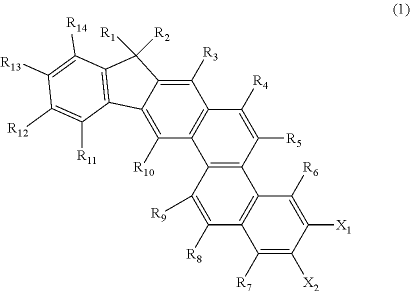
where R₁ to R₁₄ are independently selected from hydrogen atoms and alkyl groups containing one to four carbon atoms;
X₁ and X₂ represent a hydrogen atom or an aryl group;
either one of X₁ and X₂ is the aryl group; the aryl group is at least one selected from the group consisting of a phenyl group, a biphenyl group, a terphenyl group, a fluorenyl group, a naphthyl group, a chrysenyl group, a triphenylenyl group, and a phenanthryl group; the aryl group may be substituted with at least one selected from the group consisting of a phenyl group, a biphenyl group, a terphenyl group, a fluorenyl group, a naphthyl group, a chrysenyl group, a triphenylenyl group, or a phenanthryl group; and the aryl group may have a substituent having an alkyl group containing one to four carbon atoms.

2. The condensed polycyclic compound according to claim 1, wherein X₁ represents the aryl group and X₂ represents the hydrogen atom.

3. An organic light-emitting element comprising:
a pair of electrodes; and
an organic compound layer placed between the electrodes,
wherein the organic compound layer contains the condensed polycyclic compound according to claim 1.

4. The organic light-emitting element according to claim 3, wherein the organic compound layer is a light-emitting layer.

5. The organic light-emitting element according to claim 4, wherein the light-emitting layer contains a host and a guest and the host is the condensed polycyclic compound.

6. The organic light-emitting element according to claim 5, wherein the guest is an iridium complex.

7. The organic light-emitting element according to claim 4, wherein the light-emitting layer emits red phosphorescent light.

8. The organic light-emitting element according to claim 3, wherein the organic compound layer contains a plurality of luminescent materials, at least some of the luminescent materials emit light of a color different from the color of light emitted from the other luminescent materials, at least one of the luminescent materials is the condensed polycyclic compound, and the organic compound layer emits white light.

9. A display device comprising a plurality of pixels, wherein at least one of the pixels includes the organic light-emitting element according to claim 3 and an active element connected to the organic light-emitting element.

10. An image information processor comprising:
an input section supplied with image information; and
a display section for displaying an image,
wherein the display section is the display device according to claim 9.

11. A lighting device comprising:
the organic light-emitting element according to claim 3; and
an AC/DC converter circuit for supplying a driving voltage to the organic light-emitting element.

12. An image-forming device comprising:
a photoreceptor;
an electrifying section electrifying a surface of the photoreceptor;
an exposure section for exposing the photoreceptor to light; and
a developing unit for developing an electrostatic latent image formed on the photoreceptor,
wherein the exposure section includes the organic light-emitting element according to claim 3.

13. An exposure device for exposing a photoreceptor, comprising organic light-emitting elements identical to the organic light-emitting element according to claim 3, wherein the organic light-emitting elements are arranged in a line.
